(19) United States
(12) Patent Application Publication
(10) Pub. No.: US 2021/0018611 A1
(43) Pub. Date: Jan. 21, 2021

(54) OBJECT DETECTION SYSTEM AND METHOD

(71) Applicant: Headlight AI Limited, London (GB)

(72) Inventors: Puneet CHHABRA, London (GB); Jameel MARAFIE, London (GB)

(73) Assignee: Headlight AI Limited, London (GB)

(21) Appl. No.: 16/982,608

(22) PCT Filed: Mar. 21, 2019
(86) PCT No.: PCT/GB2019/050802

§ 371 Date: Sep. 21, 2020

(30) Foreign Application Priority Data
Mar. 21, 2018 (GB) 1804539.3

(51) Int. Cl. G01S 13/86; G01S 17/18; G01S 17/87; G06K 9/00; G06K 9/62; G01W 1/02; H01L 31/107

(52) U.S. Cl. CPC G01S 13/865; G01S 17/18; G01S 17/87; H01L 31/107; G06K 9/6263; G01W 1/02; G06K 9/00805

(57) ABSTRACT

A system (100) for detecting at least one object in environmental conditions of poor visibility, comprising: a ranging device (10, 30) configured to receive a set of signals; at least one further ranging device (50) configured to receive at least one further set of signals; and a processor (40) configured to gate the set of signals based on the at least one further set of signals thereby to identify at least one subset of the set of signals, the at least one subset of signals relating to at least one object.

The present invention relates to a system for detecting at least one object in environmental conditions of poor visibility. More particularly, the present invention relates to such a system that is used as part of a navigation system for a machine, in particular a vehicle. The invention extends to a corresponding method.

Autonomous systems which sense their surroundings (such as moving or static machines such as vehicles, whether such vehicles are terrestrial, aerial or marine vehicles) may fail to operate properly when confronted with conditions of poor visibility, for example in adverse weather conditions such as heavy fog, heavy rain, snow, and dust. Current 3D vision systems incorporated in such autonomous systems for the purpose of object detection and/or navigation often fail to distinguish between particles in the air (e.g. water particles due to fog, rain and snow) and true obstacles (or other objects of relevance).

Existing systems offer a solution based on either radar (radio waves) on its own, or an integrated system that may use ultrasound or 2D imagery. Recent advances in high frequency, long-range radar and synthetic aperture radar (SAR) enable the detection of objects in dense fog and rain; however, such systems generally provide only relatively poor quality resolution (such systems may also take a long time to build an image, making them inappropriate for moving applications such as vehicles).

Aspects and embodiments of the present invention are set out in the appended claims. These and other aspects and embodiments of the invention are also described herein.

According to at least one aspect described herein, there is provided a system for detecting at least one object in environmental conditions of poor visibility, comprising: a ranging device configured to receive a set of signals; at least one further ranging device configured to receive at least one further set of signals; and a processor configured to gate the set of signals based on the at least one further set of signals thereby to identify at least one subset of the set of signals, the at least one subset of signals relating to at least one object.

The ranging device preferably comprises an emitter of electromagnetic radiation, such as a laser.

Preferably, the at least one object is not any of: an aerosol (e.g. fog, dust, steam, smoke, haze); one or more airborne particles; and precipitation. This enables detection of other objects in conditions of poor visibility, where other systems may instead detect airborne particles and/or precipitation.

The at least one further ranging device is any kind of active or passive ranging, imaging or other device that measures the current state of the environment. Preferably the ranging device is light-based and the at least one further ranging device is not light-based, where optionally the at least one further ranging device comprises a radar device and/or a sound-based ranging device, such as an ultrasound-based ranging device. Preferably the at least one further ranging device provides greater penetration of airborne particles and precipitation than the ranging device. This may enable good operation of the system in all types of weather.

The ranging device and/or the at least one further ranging device may be arranged to operate continuously, where preferably the processor is configured to record the receipt of signals in the set of signals over a time period and more preferably the processor is configured to generate at least one histogram relating to the set of signals.

Preferably, the processor is configured to control the properties of the gating and/or to gate the set of signals in (substantially) real time (i.e. any delay in gating is minimal or near-minimal given the technical constraints of the system).

The system may further comprise a classification module configured to identify the at least one object related to the at least one subset of signals by reference to a plurality of predetermined classes. This enables further information about the object to be determined, where the classifier may, for example, be further configured to classify the at least one object by one or more of: type; shape; material; and movement. The classification module may also be referred to as an “AI module” or simply “AIM”.

The classification module is preferably configured to identify the at least one object by identifying features of the subset of signals; and comparing the identified features against the plurality of predetermined classes. Preferably, the identifying and comparing are performed simultaneously.

Preferably, the classification module comprises a trained classifier.

Preferably, the classification module is configured to receive feedback and update the plurality of predetermined classes in response to said feedback. In this way the performance of the classifier can be improved.

Preferably, the classification module is configured to operate in real time.

Preferably, the classification module is configured to identify the at least one object based on input from the at least one further ranging device.

The system optionally comprises at least one further sensor, wherein the classification module is configured to identify the at least one object based on input from the at least one further sensor. The at least one further sensor may comprise one or more of: an inertial measurement unit, an accelerometer, a camera, and a Global Navigation Satellite System (GNSS) or Global Positioning System (GPS) receiver. Preferably, the at least one further sensor comprises at least one sensor which is not a GNSS/GPS receiver, where this advantageously may allow operation in GNSS/GPS denied environments.

The classification module may be configured to identify the at least one object based on weather data.

Optionally, the processor is configured to provide a dictionary of elementary shape functions for a waveform; determine a vector relating to the contribution of each elementary function in the dictionary to the waveform of at least one signal in the set of signals; and classify the waveform of the at least one signal based on the vector thereby to detect at least one object. Preferably, the determining and classifying are performed simultaneously and/or are performed in a single step.

Preferably, the ranging device comprises a light detection and ranging (LIDAR) device and the set of signals comprises reflected photons originating from a transmitted pulse of the ranging device. Advantageously, LIDAR devices have high resolution.

Preferably, the LIDAR device comprises a plurality of single photon detectors for receiving reflected photons. Single photon detectors are, advantageously, sensitive enough to detect very low power signals. Preferably, the plurality of single photon detectors comprises single-photon avalanche diodes (SPADs).

Preferably, the plurality of single photon detectors are tuned to receive a plurality of different wavelengths of reflected photons. This allows differentiation between received signals of different wavelengths.

Preferably, the LIDAR device has a 360-degree field of view. Alternatively, 2D LIDAR may be used. In general, a ranging device having any field of view (using 2D or 3D ranging) may be used.

The processor may be further configured to control the operation of the ranging device (and/or make decisions) based on data relating to environmental conditions received from at least one sensor (and/or the classifications). Preferably, the at least one sensor is part of one or more of: the ranging device; and the at least one further ranging device.

According to at least one (further) aspect described herein, there is provided a system for detecting at least one object in environmental conditions of poor visibility, comprising: a ranging device configured to receive a set of signals; at least one sensor for receiving data relating to environmental conditions; and a processor configured to control the operation of the ranging device in dependence on the received data (and/or inferences made based on that data).

Preferably, the at least one sensor is part of a further ranging device. Preferably, the further ranging device comprises a radar device and/or a sound-based ranging device, such as an ultrasound-based ranging device.

Preferably, the processor is configured to control the operation of the ranging device based on determined correlations between the ranging device and the at least one sensor. Improvements in mapping, especially simultaneous localisation and mapping (SLAM) may be possible in harsh environments as a result of this.

Preferably, the at least one sensor comprises one or more of: an inertial measurement unit, an accelerometer, a camera, and a Global Navigation Satellite System (GNSS) or Global Positioning System (GPS) receiver. Preferably, the at least one sensor comprises at least one sensor which is not a GNSS/GPS receiver, where this advantageously may allow operation in GNSS/GPS denied environments.

Preferably, the at least one sensor comprises a receiver for receiving data via a data network. This receiver may, for example, allow the receipt of data from a mobile communications network. In particular, data relating to weather conditions may be received which may be transmitted and/or requested from a remote server.

Preferably, the system comprises a plurality of different sensors external to the ranging device for receiving data relating to environmental conditions.

The processor may be configured to control the operation of the ranging device by controlling one or more of: frequency, frequency modulation, pulse width; pulse repetition rate, field of view, resolution, beam width; wavelength; and power. Preferably, the processor is configured to control the operation of the ranging device in real time.

Optionally, the processor is configured to control the gating properties. Preferably, the processor is configured to control the gating properties in real time.

Preferably, the ranging device is configured to receive further data relating to the environmental conditions; wherein the processor is configured to control the operation of the ranging device in dependence on the received further data.

Also described herein is a system for navigation comprising a system as described above, wherein the at least one object is relevant for navigation.

According to at least one (further) aspect described herein, there is provided a method of detecting at least one object, comprising the steps of: receiving a set of signals via a ranging device; providing a dictionary of elementary shape functions of a waveform; determining a vector relating to the contribution of each elementary shape function in the dictionary to the shape of the waveform of at least one signal in the set of signals; and classifying the waveform of the at least one signal based on the vector thereby to detect at least one object.

This may allow the extraction of multiple peaks and assignment of target labels in a single step, even if training data is not or partially made available. This may allow a point cloud/image to be generated in which all the points in the point cloud or the image are labelled (without a separate labelling step). Due to its automatic detection (peak extraction) and discrimination behaviour, the method may produce labelled data at a high speed, i.e. a by-product to fast data labelling. In general the method is high speed, whereby it may be suitable for real-world purposes (in particular for navigation), and is non-complex in time and memory terms.

The method operates on the basis that an individual peak is composed of elementary shape functions (mathematically modelled or learnt from the data) and its coefficient or contribution vector is a significant parameter in class separation. An orthonormal (rather than binary) membership of a plurality of classes may be provided by the method.

Preferably, the determining and classifying are performed simultaneously. The method may further comprise identifying peaks in the at least one set of signals, wherein the vector is determined based on at least one peak. The peaks may be ranked, and a vector may be (repeatedly) determined in respect of a plurality of peaks, wherein the peaks are processed in ranked order. A vector may be (repeatedly) determined in respect of a plurality of peaks until a stop criterion, optionally a pre-determined threshold is met. The method may further comprise determining sparse parameters of the waveform from the identified peaks, preferably wherein said sparse parameters are used in the determination of the vector. The method may further comprise generating the dictionary based on the set of signals (optionally based on sparse parameters of detected peaks). The method may further comprise detecting at least one object, preferably wherein said detecting comprises detecting at least one of: the class of the object; the type of the object; the distance of the object from the ranging device; and the material of the object.

According to at least one (further) aspect described herein, there is provided a system comprising: a non-transitory memory storing instructions or local data; and one or more hardware processors coupled to the non-transitory memory and configured to execute the instructions from the non-transitory memory to cause the system to perform operations comprising the steps of the method described herein.

Also described herein is a sensing device comprising a system as described above.

Also described herein is a vehicle comprising a system as described above. Optionally, the vehicle is a lightweight vehicle. Preferably, the vehicle is configured for use in one or more of the following environments: underground; underwater; on a road; on a railway, on the surface of water, in high altitude; and in low altitude. Preferably, the vehicle is one of: a mobile robot; an unmanned aerial vehicle (UAV), an unmanned underwater vehicle (UUV), a submarine, a ship, a boat, a train, a tram, an aeroplane, and a passenger vehicle such as a car.

According to (another) aspect described herein, there is provided a method of detecting at least one object in environmental conditions of poor visibility, comprising: receiving a set of signals via a ranging device (optionally wherein the ranging device comprises a laser); receiving at least one further set of signals using at least one further ranging device; and gating the first set of signals based on the at least one further set of signals thereby to identify at least one subset of the set of signals, the at least one subset of signals relating to at least one object.

According to (another) aspect described herein, there is provided a method of controlling an object detection system, comprising the steps of: providing an object detection system comprising a ranging device (optionally having a laser); receiving data relating to environmental conditions from the at least one sensor; and controlling the operation of the laser in dependence on the received data.

Also described herein is a computer program product comprising software code adapted to carry out a method as described above.

By gating the set of signals based on a further set of signals, parts of the set of signals relating to particular objects or obstacles may be distinguished from parts of the set of signals that relate to airborne particles or precipitation. This may allow effective use of a ranging device (optionally including a laser such as a LIDAR device) in conditions of poor visibility, thereby allowing for improved resolution of object detection and/or visualisation in conditions of poor visibility.

According to at least one aspect described herein, there is provided a system for detecting at least one object in environmental conditions of poor visibility, comprising a ranging device configured to receive a set of signals, the ranging device optionally comprising a laser; at least one sensor for receiving data relating to environmental conditions; and a processor configured to control the operation of the ranging device in dependence on the received data.

By controlling the operation of the ranging device based on received data relating to environmental conditions (as detected by other sensors), the operation of the ranging device may be adapted based on the conditions, which may thereby provide for improved operation of the ranging device.

In general, an integrated approach is provided, in which an automatic gating mechanism uses backscattered (radar) signals to control a (laser) ranging system (or vice versa). The described on-chip algorithms automatically find the best parameter setting for gating on the returning backscattered (laser) pulses.

The invention extends to methods, systems and apparatus substantially as herein described and/or as illustrated with reference to the accompanying figures.

The invention also provides a computer program or a computer program product for carrying out any of the methods described herein, and/or for embodying any of the apparatus features described herein, and a computer readable medium having stored thereon a program for carrying out any of the methods described herein and/or for embodying any of the apparatus features described herein.

The invention also provides a signal embodying a computer program or a computer program product for carrying out any of the methods described herein, and/or for embodying any of the apparatus features described herein, a method of transmitting such a signal, and a computer product having an operating system which supports a computer program for carrying out the methods described herein and/or for embodying any of the apparatus features described herein.

Any feature in one aspect of the invention may be applied to other aspects of the invention, in any appropriate combination. In particular, method aspects may be applied to apparatus aspects, and vice versa. As used herein, means plus function features may be expressed alternatively in terms of their corresponding structure, such as a suitably programmed processor and associated memory.

Furthermore, features implanted in hardware may generally be implemented in software, and vice versa. Any reference to software and hardware features herein should be construed accordingly.

As used herein, the term ‘conditions of poor visibility’ preferably connotes environmental conditions in which the operation of any ranging or sensing systems using electromagnetic waves is in any way impaired (as compared to the operation of said systems in other possible environmental conditions), in particular wherein said environmental conditions are those in which a high volume of airborne particles or objects associated with precipitation are present (as compared to other possible environmental conditions)—such environmental conditions include, for example, rain, fog, smoke, snow, sleet, haze, dust, and smog; more particularly wherein said electromagnetic waves are at wavelengths that are associated with any or all of: visible light, ultraviolet light, and (near) infrared light. Other possible examples of ‘conditions of poor visibility’ may include dark or low light conditions; conditions of high humidity; and conditions in which the ranging or sensing system transmits and/or receives signals through a medium other than air, such as water or another fluid.

As used herein, the term ‘gate’ (where used as a verb) preferably connotes processing a dataset to select only those portions of the data between specified limits, more preferably between specified time intervals or between specified amplitude limits.

As used herein, the term ‘light’ preferably connotes any or all of: visible light, ultraviolet light, and near infrared light; more preferably electromagnetic radiation having a wavelength between 100 nm and 100 μm; yet more preferably between 250 nm and 10 μm.

As used herein, the term ‘object’ preferably connotes an object that is intended to be detected by the system and/or is a target for the system; more preferably an object that is relevant for navigation and/or mapping (in particular for a vehicle or device including the system). As used herein, all references to the term ‘object’ in the singular sense should be understood to additionally refer to ‘objects’ in a plural sense, and vice versa.

As used herein, the term ‘waveform’ preferably connotes a property of a wave that varies with time; preferably wherein such a property is graphed with time on the horizontal axis and/or is processed as a geometric shape.

As used herein, the term ‘dictionary’ preferably connotes a set of functions; preferably wherein said functions are basic elements of a particular signal.

As used herein, references to light-based sensors′, ‘lasers’ or ‘LIDAR’ should be understood as also referring to any kind of active or passive sensing system, unless the relevant part of the description refers specifically to particular properties of light-based sensors′, ‘lasers’ or ‘LIDAR’.

It should also be appreciated that particular combinations of the various features described and defined in any aspects of the invention can be implemented and/or supplied and/or used independently.

The invention will now be described, purely by way of example, with reference to the accompanying drawings, in which:

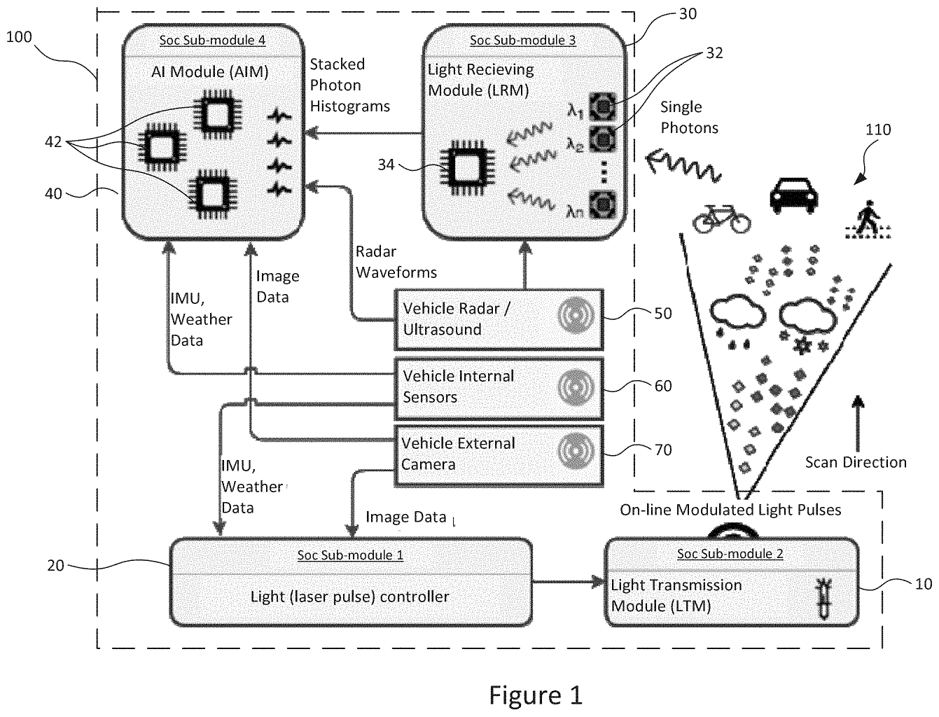

FIG. 1 is a schematic diagram of an object detection system in an aspect of the present invention;

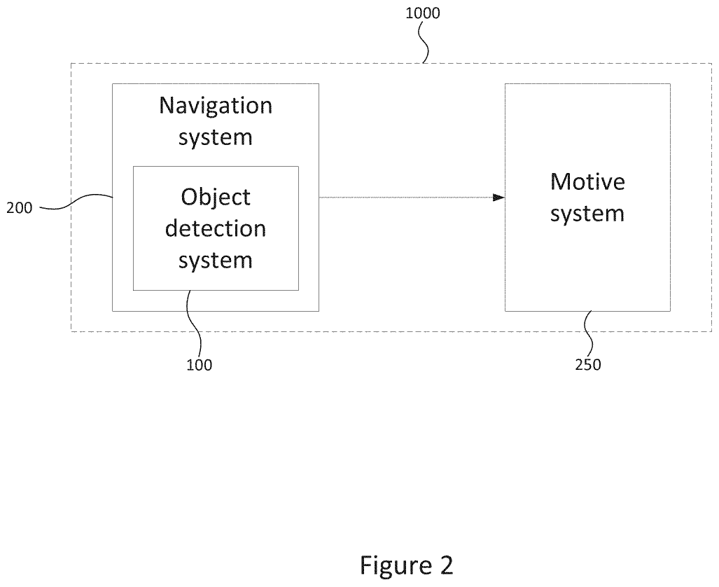

FIG. 2 is a schematic diagram of a vehicle incorporating the object detection system;

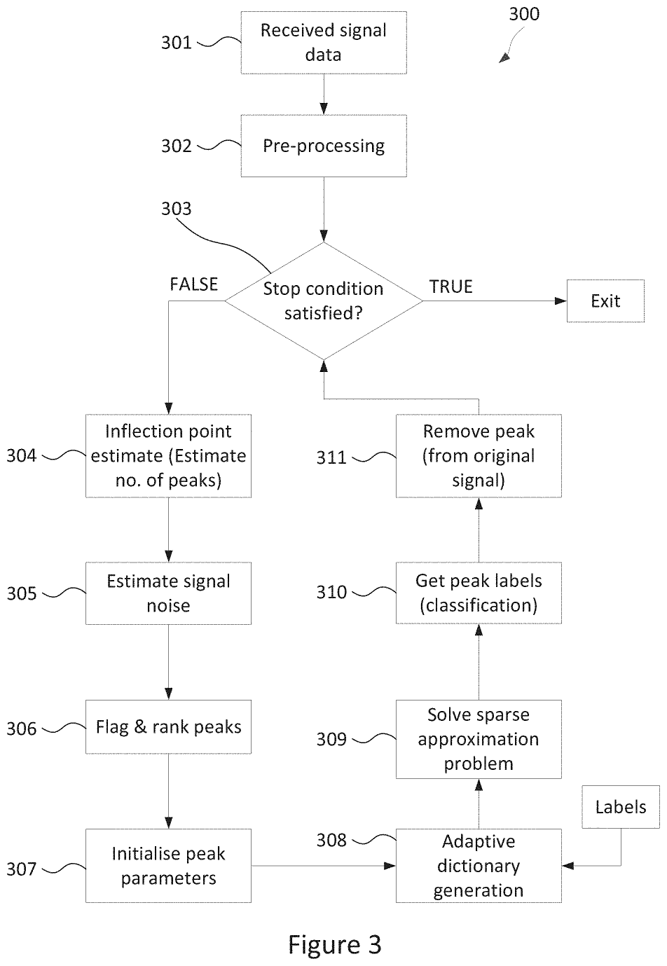

FIG. 3 shows a flow diagram of a method performed by an AI module of the system;

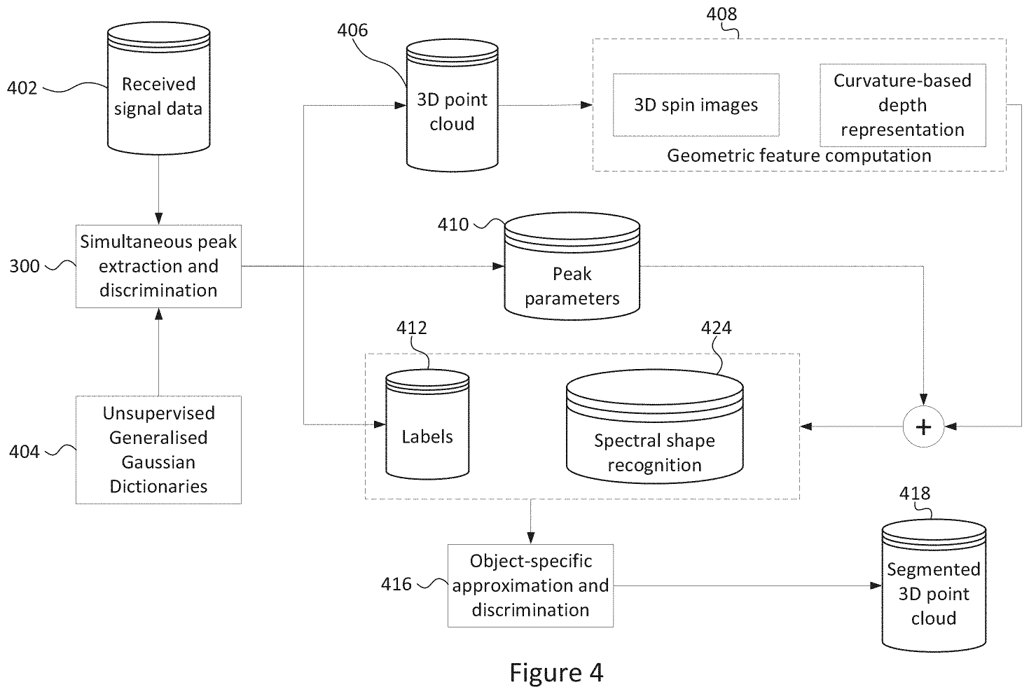

FIG. 4 shows an architecture diagram of how received signal data is handled by the processor of the system;

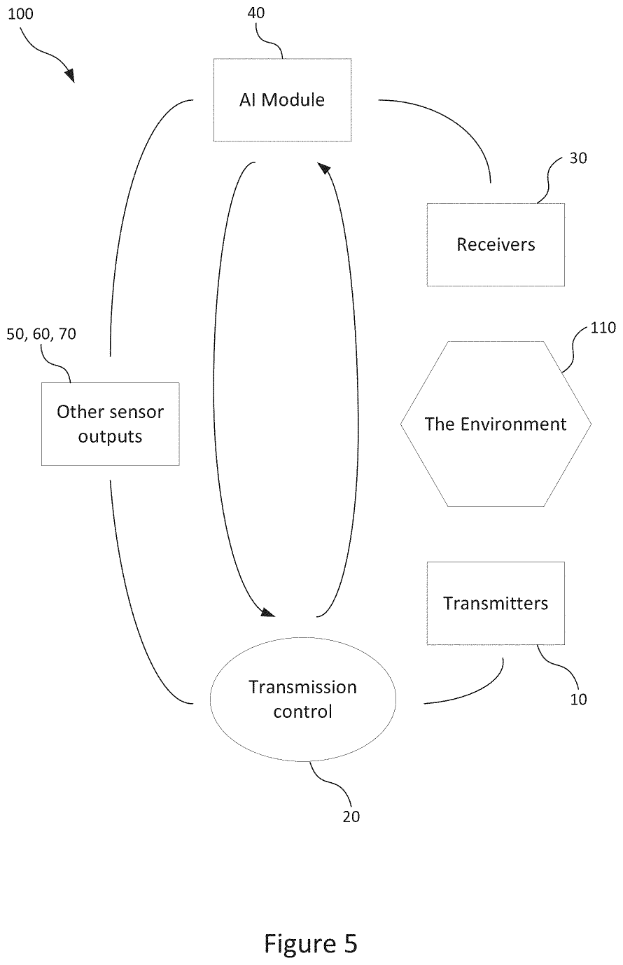

FIG. 5 shows a schematic diagram showing the control mechanism for the transmitting parts of the system;

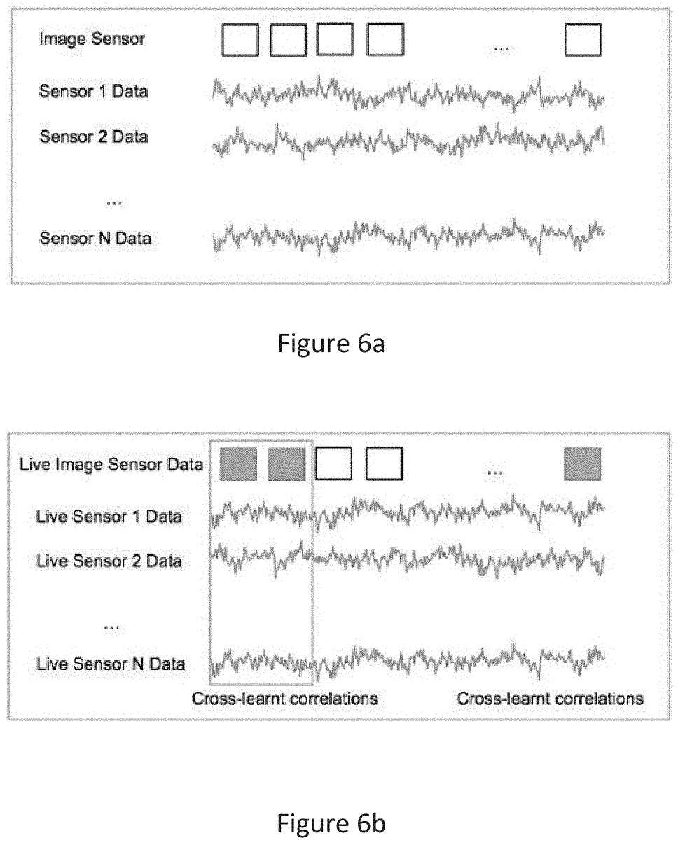

FIGS. 6a and 6b show examples of different sensor data received by the system; and

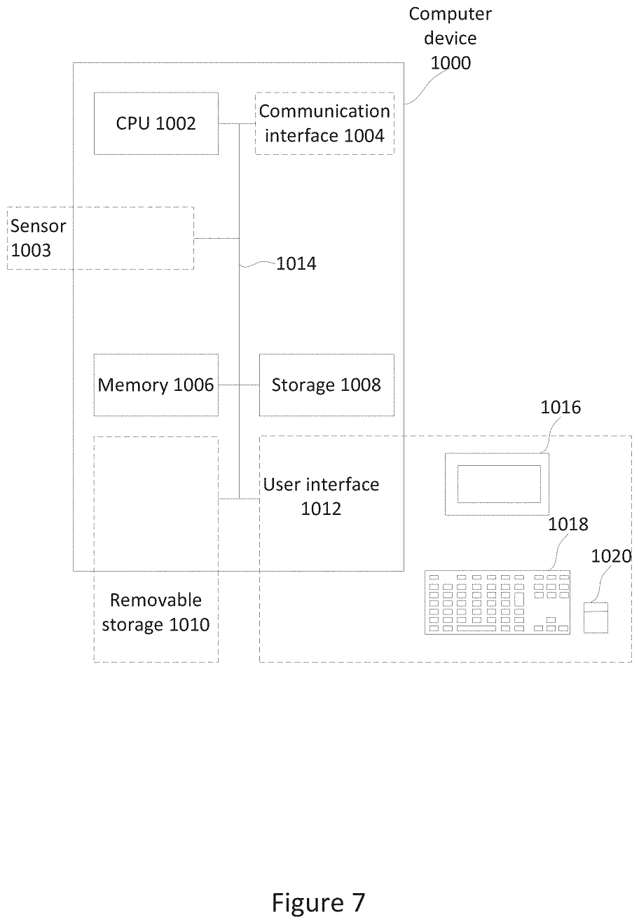

FIG. 7 shows a computer device suitable for implementing the described methods and/or forming part of the described system.

### SPECIFIC DESCRIPTION

Various automatic and semi-automatic 3D shape acquisition/object detection systems are known. In broad terms, these can be categorised as optical shape acquisition systems (including active imaging systems such as imaging radar, triangulation using light (in particular, light detection and ranging or LiDAR systems), interferometry, active stereo, active depth from defocus, and passive imaging systems such as stereo range/depth imaging (2.5D), shape from shading and silhouettes, and depth from focus/defocus) and non-optical shape acquisition systems (based on, for example, any of microwave, radar, and sonar).

Passive optical shape acquisition systems generally use stereo or monocular imagery to estimate the distance of each point in an image to the origin of the camera, thereby to produce a 2.5D point cloud. Such point clouds are not true 3D, since the scans are along the x and y axis alone. Their low cost makes them an attractive solution for indoor robotics applications. However, they lack sufficient range for many uses and their sensitivity deteriorates in bad weather, e.g. dense fog and low light. Recent advances in this field have been on the algorithm front, e.g. reducing the data processing time or improving on accuracy.

Active optical shape acquisition systems operate on the principle of a pre-defined energy chirp (often EM waves, e.g. radio or light) being transmitted using either a pulsed system or sent out in a flash (illuminating a large area in front of the sensor). The backscattered energy/signal is recorded using a sensor, and is then filtered and processed. The processed signal can be treated as a signature for target identification, or the return time (time-of-flight) can be used for depth estimation, resulting in a point cloud.

Current advances in radar systems (using radio waves) are a good solution to detect object/targets in conditions of poor visibility (in particular poor weather conditions, such as dense fog or rain). However, they lack sufficient resolution for many uses and suffer from a high degree of false detections, especially in the presence of metallic or highly reflective objects, e.g. other vehicles, rail tracks, etc.

Active optical shape acquisition systems based on light (in particular, LIDAR) may be advantageous for many applications (in particular, vehicle navigation) as compared to other systems due to the relatively high resolution that they afford as a result of their exceptionally small beam footprint (as low as 1 picosecond or needle pulse), low divergence relative to other systems, and high possible repetition rate. The high resolution of these systems may allow high quality 3D mapping data to be produced.

However, such systems tend to perform poorly in conditions of poor visibility as a result of airborne particles (e.g. dust or smoke particles) and/or precipitation (e.g. rain or snow) altering the way in which signals are backscattered, for example by generating an increased volume of spurious returned signals. Additionally, certain objects (in particular, surfaces such as pavements or roads) produce different results when wet (e.g. as a result of rain), further altering the returned signal. The alteration in the returned signals may make it very difficult, or even impossible, to isolate parts of the signals which correspond to objects which are intended to be detected, impairing the performance of these systems. Faint return signals (corresponding to objects of interest) may also be concealed by the spurious returned signals—this may further impair performance.

FIG. 1 is a schematic diagram of an object detection system 100, which is generally provided on or as part of a vehicle (such as a car, train, boat, plane, or unmanned aerial vehicle (UAV)). The vehicle on which the system 100 is provided may be controlled directly or remotely by a human operator, or alternatively may operate autonomously.

The object detection system 100 comprises a ranging device in the form of a LIDAR device, which is made up of a plurality of modules—a light transmission module (LTM) 10 (i.e. a laser and supporting components), a light controller module (LCM) 20 for controlling the light transmission module, and a light receiving module (LRM) 30 for receiving backscattered signals originating from pulses of light produced by the LTM. The LRM 30 comprises a plurality of detectors 32 for receiving backscattered photons and a processor 34 provided in communication with the plurality of detectors. The object detection system 100 further comprises an AI module (AIM) 40 (also referred to as a ‘classification module’) for receiving an input from the LRM 30 (specifically, from the processor 34).

Together with the aforementioned ‘modules’, the system 100 further comprises at least one further ranging device 50, which is generally either (or both of) a long range or short range radar sensor or a short-range ultrasound sensor (it will be appreciated that sensing based on infrasound or audible sound could alternatively be used in certain applications). Both of these types of further ranging device are not light-based (unlike the previously mentioned LIDAR device), and provide improved penetration of airborne particles and precipitation than the LIDAR device, meaning that any reduction of performance of such ranging systems in conditions of poor visibility is not as significant as the reduction of performance of the LIDAR device in conditions of poor visibility. The at least one further ranging device 50 is configured to communicate with the LRM 30 (in particular, the processor 34) and the AI module 40.

The system 100 also further comprises one or more further sensors 60 (which may be described as ‘internal sensors’) and a camera 70 mounted on the vehicle. The further sensors 60 may comprise, for example, an inertial measurement unit (IMU) for the vehicle, a Global Navigation Satellite System (GNSS) or Global Positioning System (GPS) receiver, an accelerometer, and a receiver for receiving data via a data network (such as a global system for mobile communications (GSM (RTM)) network), in particular data relating to weather conditions, which may be transmitted and/or requested from a remote server.

The LIDAR device of the system 100 operates by the LCM 20 controlling the LTM 10 to transmit pulses of light (of a specified wavelength) away from the system (and/or the vehicle). The pulses of light are backscattered from the surroundings 110 (which include airborne particles, precipitation, roads, pavements, and objects/obstacles of relevance for navigation, such as other vehicles and pedestrians, for example), and a portion of these backscattered signals are received at the detectors 32 of the LRM 30. The detectors 32 are single photon detectors (such as single-photon avalanche diodes (SPADs)), which are sensitive enough to detect very low power signals, including individual photons (it will be appreciated that other kinds of detectors may be used). The detectors 32 may be tuned to particular ranges of wavelengths generally in dependence on the wavelengths used by the laser of the LTM, with a variety of detectors tuned to different wavelength ranges being used in order to differentiate between received signals of different wavelengths.

The LIDAR device is configured to transmit and receive a set of backscattered signals from 360 degrees around the system/vehicle. Accordingly, the LIDAR system may (as an example) be configured as a rotating system which continuously rotates so as to scan around the area, or alternatively as a system having a plurality of LTMs 10 and/or LRMs 30 which are capable of transmitting and receiving 360 degrees around the system/vehicle, optionally where the fields of view of the LTMs 10 and/or LRMs 30 overlap to a certain extent. In one example, a plurality of such ‘overlapping’ LTMs 10 are used together with a single LRM 30 having a field of view of 360 degrees (i.e. being capable of receiving signals from anywhere around the system/vehicle without moving or rotating).

The detectors 32 are configured to continuously receive a set of signals over time, where the time at which signals are received are recorded by the processor 34, together with the amplitudes, wavelengths, and optionally other properties of the signals themselves. This allows histograms (i.e. functions counting the number of signals falling into one of a plurality of disjoint categories/bins) of the set of signals to be built by the processor, where the categories of the histogram may relate to signal amplitude, wavelength, or another property.

In conditions of poor visibility, the received set of signals are expected to be noisy and indefinite relative to those obtained in good conditions (for the reasons previously explained with reference to the operation of active optical shape acquisition systems). Accordingly, it is difficult to gate the histograms (i.e. select portions of the histogram relating to objects of interest, rather than airborne particles or precipitation—in other words, to find relevant subsets of the set of received signals) generated on the basis of the received set of signals on the basis of the received set of signals for the LIDAR system itself.

As mentioned, the processor 34 is also configured to receive data relating to received signals from the at least one further ranging device 50. This data can be used by the processor to gate the histograms of the received LIDAR signal around regions of interest (which generally correspond to one or more objects that are not airborne particles or objects associated with precipitation), since the data from the at least one further ranging device is expected to more accurately correspond to equivalent data received in good conditions. This can be performed in a variety of ways—for example, features can be identified in the data from the at least one further ranging device, and corresponding features can be identified in the histograms. In another example, a modifier or smoothing factor for the histograms can be calculated based on a classification related to the conditions calculated from the received data from the at least one further ranging device (in poor conditions) and historic data from the at least one further ranging device (in good conditions). Such examples may of course be combined so as to further improve the accuracy of the gating. It will be appreciated that the processor may be used to control the properties of the gating.

By using a combined approach relating to multiple ranging devices, the strengths of both optical/light-based systems such as LIDAR (i.e. high resolution) and non-light based systems such as radar and ultrasound (i.e. reduced loss of performance in conditions of poor visibility) can be exploited, allowing ranging, object detection, and shape recognition in conditions of poor visibility at high resolution. Notably, this technique is based on signal processing using a plurality of signals (and is not, for example, based on data fusion using a trained classifier)—accordingly, a more robust and predictable system may be provided. The use of gating as described may also serve to make the SPADs used as the detectors 52 even more sensitive in extreme weather conditions.

The end result of said gating is one or more subsets of the received set of backscattered signals, in the form of gated histograms (i.e. histograms in which certain data or categories of the histogram has been removed). The processor 52 is configured to store the gated histograms, for example in a data store (not shown) of the system. The remainder of the set of signals/the histograms may be disregarded and so may not be stored—this may save on storage space, while allowing important parts of the received signal (relating to objects) to be retained.

The AI module 40 is configured to receive an output from the processor 52, which generally consists of one or more gated histograms relating to one or more detected objects. The AI module consists of one or more processors 42 configured to implement a trained classification model, which is configured to receive at least an input from the LRM 30 and which is used to produce results that are useful for the particular purpose that the system is used for e.g. navigation, in particular by identifying the detected object. For example, the AI module may be configured to use the received gated histogram to classify the object related to the histogram by type/identity (e.g. pedestrians, cyclist, car, van, animal), whether the object is moving or static (including, optionally, the speed of movement), shape of the object, and the material of the object (e.g. metallic, asphalt, or other). It will be appreciated that a variety of other classifications are possible, and that the classifications may inform each other to some extent—for example, the material of the object may be used to classify the type of the object.

The AI module 40 also receives data (directly) from the at least one further ranging device 60, which provides further data for use in said classification process. The system 100 accordingly includes cross-learning across at least two sensor modalities (for the purpose of control). The AI module may also receive input from the internal sensors 60 and the camera 70, which may provide yet further data for use in said classification process.

The AI module 40 generally operates by receiving the gated histograms, detecting/extracting the features (such as peaks and troughs) in the histograms, and classifying the histograms by reference to a number of predetermined classifications. All of these steps are performed generally simultaneously, thereby to allow for the AI module to produce a real-time output (such that this output is useful for real-time navigation). In one particular example, features in the histogram corresponding to both the shape (geometry) and material of the object are extracted—the shape and material are then classified, which may enable a classification of the type of object to be determined. Further details of the operation of the AI module are described later on.

Since the AI module implements a trained classifier, the classifier is generally updated in response to feedback (i.e. it receives further training), which may involve updating the predetermined classifications.

The object detection system 100 also includes a further adaptation to improve operation of the system in conditions of poor visibility, in that the LCM 20 is configured to control the LTM 10 in dependence on the detected environmental conditions. The LCM receives an input from the internal sensors 60 and the camera 70, and uses such inputs to determine one or more classifications for the environmental conditions. The one or more classifications may, for example, relate to distinct weather conditions (e.g. ‘light rain’, ‘heavy fog’, etc.).

The LTM 10 may then be controlled by the LCM 20 in dependence on the one or more classifications. Specifically, one or more operating parameters of the laser of the LTM may be controlled—such parameters include wavelength, power, pulse width, pulse repetition rate, field of view, resolution, frequency, frequency modulation, and beam width. This allows, for example, a signal with a higher power and smaller pulse width may be transmitted in conditions of poor visibility so as to receive a sufficiently large backscattered signal, whereas a signal with a lower power and larger pulse width may be used in good conditions so as to save power. Importantly, the LCM is arranged to determine the operating parameters for the LTM in real time and in direct dependence on the sensor input, so as to ensure that the operation of the LTM is appropriate for the current conditions.

Using sensors external to the LIDAR system as a basis for controlling the laser, rather than, for example, the backscattered returned signal may allow for improved reliability and accuracy in control—as previously explained, backscattered returned signals tend to be inaccurate and unpredictable in conditions of poor visibility. Optionally, the backscattered returned signal may additionally be used as an input for controlling the laser.

Optionally, the LCM 20 may be provided in communication with the AI module 40, which may be configured to learn optimal control parameters for specific environmental conditions and to communicate such parameters to the LCM. In a similar way, the AI module may also be configured to learn control parameters for the at least one further ranging system, which may comprise at least one controller to allow the system to be controlled accordingly. Such optimal control parameters may be dynamically updated in response to feedback. Further details of the way in which the AI module may control the LCM/LTM will be described later on.

The object detection system 100 acts to distinguish “target” objects from particulates such as fog and aerosol particles. Once this has been performed, the system 100 may be capable of removing such non-target objects from sensor data, in particular any image data captured via the camera 70. Such image data may be presented to an occupant of a vehicle or another party.

FIG. 2 shows a schematic diagram of a vehicle 1000 implementing the object detection system 100. The vehicle comprises a navigation system 200 incorporating the object detection system 100, and a motive system 250. The navigation system is arranged to receive an input from the object detection system (more specifically, the AI module 40) relating to detected objects proximate the vehicle, including their proximity, type, movement, etc.

The navigation system is configured to use this input to determine whether any changes need to be made to the movement of the vehicle, which determination may be further based on parameters related to the present movement of the vehicle (e.g. position, velocity, and acceleration, as determined by sensors of the vehicle such as the IMU and/or GNSS/GPS receiver) and a goal (for example, ‘travel to destination X’).

If any changes are required, a signal is output from the navigation system to the motive system (which comprises a device for causing movement of the vehicle, such as a motor, transmission, and wheels, or a rotor and motor, and a processor for controlling the same), which causes the vehicle to move accordingly.

Although the above description relates principally to a system based on the transmission and receipt of a light based signal, in particular by use of LIDAR, any kind of signal may be transmitted instead of light as long as such a signal produces a detectable backscattered return signal from the environment. Although as previously described the particular use of an optical/light-based ranging device having signals which are gated by reference to a signal received via a non-light-based ranging device may have particular benefits, the described system will work with any signal capable of producing a detectable backscattered return signal. Examples of other such signals which may be transmitted and the backscattered return measured include any kind of signal based on electromagnetic radiation (in particular RADAR), and ultrasound. The light transmission module 10 may also therefore be referred to as a “signal transmission module” (STM) or “waves transmission module” (WTM). Correspondingly the light controller module 20 may be referred to as a “signal controller module” (SCM) or “waves controller module” (WCM), and the light receiving module 30 may be referred to as a “signal receiving module” (SRM) or “waves receiving module” (WRM). As used herein those terms may be used synonymously.

Further details of the operation of the AI module 40 will now be described. In general terms the AI module 40 acts to analyse and discriminate time-series signals generated by any active sensing device (a device that transmits some form of energy, e.g. light or radio), e.g. the LTM 10 and/or the wider LIDAR device, thereby to identify features in the signals (and thereby identify objects).

In particular, the AI module 40 is capable of extracting multiple peaks from the time-series signal, the peaks corresponding to a point in space, i.e. distance to an object; and classifying them (e.g. into different classes, such as man-made terrain, buildings, trees, rain, fog, smoke or any aerosol). Such multiple peak extraction and classification is performed simultaneously.

Before such processing occurs, the backscattered energy pulse (transmitted signal) is gated to form a histogram, a full-waveform, whose nature depends on several factors, e.g., the laser wavelength, surface geometry and transmission medium. Such gating may be performed with reference to received signals from the at least one further ranging device 50 (as previously described), or may in an alternative simply be on the basis of time-gating (i.e. the round-trip time of a transmitted pulse). It will be appreciated that such histograms provide an input signal approximating the waveform of the backscattered signal (being made up of a plurality of samples).

FIG. 3 shows a flow diagram of the method 300 performed by the AI module. The method 300 may be referred to as a method of peak extraction and discrimination. In a first step 301, backscattered sensor data from any active/passive sensing device is received and is gated into histograms as previously described. Such a histogram may also be referred to as a “waveform”—in that it forms a model of, or approximates, the wave properties (e.g. frequency, wavelength, and amplitude) of the backscattered signal (i.e. the “shape” of the wave).

In a second step 302, the waveform is pre-processed by smoothing the original waveform with a Gaussian filter of a pre-defined half width. This may improve the signal-to-noise ratio of the signal. The choice of the half-width can be tailored to the sensor system, learnt from the data, learnt as part of a calibration process, or can be tailored to the half-width of the impulse response (which is known in most cases). If the half-width is unknown, then the return pulse from a calibration target (e.g. a Spectralon response at normal incident angle) or a flat surface can be used. The integrated area of the smoothing function is set to one in order to maintain the energy level (i.e. photon counts) of the original waveform. This is also a coarse way of diminishing false inflection points caused due to random system or atmospheric noise (e.g. dark photons).

In a third step 303, the method checks whether a pre-determined stop criteria is satisfied. The stop criteria relates to a maximum number of peaks being detected in a particular signal or a reconstruction error being detected as being below a certain threshold. Either of these conditions being satisfied may indicate that the processing performed is sufficient for classifying the waveform/signal as belonging to a particular class (and thereby to identify an object). In an alternative, the AI module may learn when to stop processing from the data.

In a fourth step 304, inflection points in the waveform are found (thereby to find an estimated number of peaks in the signal, since the number of peaks needed to approximate a waveform can be derived from the inflection points within that waveform). It will be appreciated that each peak may represent an object/target in space. By doing this, the waveform is decomposed into n elementary elements. In a fifth step 305, background noise in the signal is estimated. This allows background noise to be taken into account in subsequent processing. In a sixth step 306, the identified peaks are flagged and ranked, and in a seventh step 307, the initial peak parameters are extracted based on the inflection points. The peak parameters may comprise, for example, position (μ), variance (σ), i.e. full-width at half maximum (FWHM) and amplitude (β).

A pre-defined set of elementary functions, known as a dictionary, is used to estimate accurate peak parameters based on the sparse solution provided by the detected signal/initial peak parameters. In other words, the peak extraction and discrimination of waveforms is modelled as a sparse approximation problem (in that a minimal set of elementary functions is used to represent a particular waveform). In a simple example, such elementary shape functions might include a family of mathematical functions having various parameters such as Gaussian functions having various parameters (e.g. standard deviations). In an optional eighth step 308, a dictionary is adaptively generated based on the initial peak parameters. The dictionary is generated on-line for each peak. Labels may be included into the adaptive dictionary for classification purposes. Alternatively, a pre-defined dictionary may be known.

In either case, in a ninth step 309, a sparse approximation problem is solved to find a best-fit set for a particular peak. In particular, the method solves for a non-negative sparse contribution vector by introducing additional constraints. A multiple parametric function (Generalized Gaussian) models for each peak with an additional parameter to control its shape. In a tenth step 310, the peak is classified based on pre-determined labels. In an eleventh step 311, the classified peak is removed from the original waveform, and the method returns to the second step 302. In this way, processing on peaks is repeated on different peaks until data that is “good enough” is acquired.

The described method may provide high resolvability, such that relatively close surfaces (˜0.05 m away) may be resolved (optionally from approximately 300 m away), and low computational complexity. Both of these benefits are particularly useful for small and lightweight vehicles such as drones. Advantageously, multiple peaks may be detected and labelled simultaneously (i.e. the decomposition and classification problem may be combined into a single mathematical formulation)—providing faster processing, among other benefits. The described method is particularly suitable for LIDAR signals, but may be used with any other kind of signal used for passive or active sensing.

In more detail regarding the fourth step 304, for a given LiDAR waveform, Iᵢ, using the positions of consecutive inflection points, t₂ₖ₋₁ and t₂ₖ, the position μₖ, half-width, σₖ and amplitude βₖ of the k^{th} peak are given by:

$${μ}_{k} = \frac{( {t}_{2 k - 1} + {t}_{2 k} )}{2} , \\ {σ}_{k} = \frac{\vert {t}_{2 k - 1} + {t}_{2 k} \vert}{2} , \\ {β}_{k} = {l}_{i} ( {μ}_{k} ) .$$

In more detail regarding the ninth step 309, for a given set of LiDAR waveforms, Lϵ [symbol] ^{B,M} and a known set of elementary functions, a dictionary, ψϵ [symbol] ^{B,N}, a non-negative sparse coefficient vector, Cϵ [symbol] ^{N}, is found, which implies the contribution of each elementary function in ψ. Hence, for a selected support set s, the sparsest solution Cₛ can be found:

$${argmin}_{{C}_{s} \geq 0} {‖ L - Ψ {C}_{s} ‖}_{2}^{2} + λ {‖ {C}_{s} ‖}_{1} , s . t . {‖ {C}_{s} ‖}_{1} \leq {T}_{0}$$

A greedy optimisation algorithm may be used under two scenarios. The greedy optimisation algorithm is as follows:

Algorithm 1:
ADAPTIVE DICTIONARY (Ψ) SELECTION

| | Initialise: s = ϕ, K = 0, C = 0 and r₀ = L | | |
|---|---|---|---|
| | Output: C | | |
| 1 | begin | | |
| 2 | \| | while k < K & max (Cₛ^{T} rₖ) > 0 do | |
| 3 | \| | \| | (i, j) ← max(C^{T} rₖ) |
| 4 | \| | \| | s ← s ∪ j |
| 5 | \| | \| | ${C}_{s} ← {arg min}_{{C}_{s} \geq 0} {\vert \vert L - {Ψ}_{s}^{T} C \vert \vert}_{2}$ |
| 6 | \| | \| | rₖ₊₁ ← L − ΨₛCₛ |
| 7 | \| | └ | k ← k + 1 |

| | | |
|---|---|---|
| 8 | └ | C\|ₛ ← Cₛ |

| | |
|---|---|
| 9 | return C |

Scenario 1) Dictionary ψ Generated using Mathematical Priors

If the dictionary matrix is unknown, a dictionary is generated for each peak based on some prior knowledge (e.g. initial peak parameters or past literature), and the sparsest solution Cₛ can be found. For example, a Generalised Gaussian peak library may be used:

$$𝒢𝒢 ( l , μ , β , ρ ) = \frac{{β}^{1 / 2}}{2 Γ ( 1 + 1 / ρ )} exp ( - {β}^{ρ / 2} {\vert l - μ \vert}^{ρ} ) ,$$

Where I is a zero vector of finite length, μ is the peak location, β is the amplitude and ρ controls the shape of the peak. Samples are then drawn using the Gamma (Γ) distribution.

In an example, a finite number of shapes (ρ=1.5-8) is used. For each p, GG samples are generated, i.e. N dictionary atoms, using arbitrary location, inverse scale; and FWHM parameters, μ, β and σ, respectively. The GG dictionary atoms are generated by a transformation of Gamma random samples. Previous methods employ several optimisation schemes that select a single peak from a library of elementary functions.

These methods are not accurate when approximating asymmetric peaks. A single peak is a composition of a family of functions. The described approach handles such a situation by extracting a sparse contribution vector which is used, along with peak parameter, as a feature vector to classify each peak.

### Scenario 2) Orthonormal Dictionary Learning

A library of peaks cannot always be modelled in advance, and/or it may not be possible to select and approximate each peak with a single function. This is due to several factors: i) unknown instrumental (e.g. different sensors have a different instrumental), ii) interaction of the unknown instrumental with different materials or geometry may result in several unknown but asymmetric shapes, iii) the shape of the transmitted signal/wave (which may be e.g. Gaussian or a double exponential pulse). The assumption made is that such peaks are repetitive. A small subset of the data may be used as a training set in order to learn new mixtures of elementary functions and their contributions. Given the training data, a single orthonormal Generalised Gaussian dictionary is used as an initialisation, which may be updated using the following algorithm:

Algorithm 2:
ADAPTIVE DICTIONARY (Ψ) LEARNING

| | Initialise: s = ϕ, K = 0, C = 0 and r₀ = L | | |
|---|---|---|---|
| | Output: C | | |
| 1 | begin | | |
| 2 | \| | while k < K & max(Cₛ^{T} rₖ) > 0 do | |
| 3 | \| | \| | (i, j) ← max(C^{T} rₖ) |
| 4 | \| | \| | s ← s ∪ j |
| 5 | \| | \| | ${C}_{s} ← {arg min}_{{C}_{s} \geq 0} {\vert \vert L - {Ψ}_{s}^{T} C \vert \vert}_{2}$ |
| | \| | \| | / / For a given sparsity level t₀ |
| 6 | \| | \| | LCₜ_{ₒ} ≈ UΣV^{T} |
| 7 | \| | \| | Ψₛ ← UV^{T} |
| 8 | \| | \| | rₖ₊₁ ← L − ΨₛCₛ |
| 9 | \| | └ | k ← k + 1 |

| | | |
|---|---|---|
| 10 | └ | C\|ₛ ← Cₛ |

| | |
|---|---|
| 11 | return C |

The original sparse approximation may be rewritten as an alternating strategy jointly optimising the coefficients C and the dictionary ψ as follows:
1. Coefficient update given a dictionary ψ:

$${argmin}_{C \geq 0} {‖ L - Ψ C ‖}_{2}^{2} + λ {‖ C ‖}_{1}$$

2. Dictionary update given a coefficient C:

$${argmin}_{Ψ} {‖ L - Ψ C ‖}_{2}^{2} , \vert {Ψ}_{n} \vert = 1 , ∀ n = 1 , … , N$$

FIG. 4 shows an architecture diagram of how received signal data is handled by the processor. Received signal data 402 and the dictionaries 404 (if any) are fed into a processing module for performing peak extraction and discrimination 300, as described. The output of the peak extraction and discrimination method is a 3D point cloud 406—this is fed into a module 408 for computing geometric features, using techniques such as 3D spin images and curvature-based depth recognition. Several geometric representations are computed, which are then combined with the previously mentioned peak parameters 410 (which provide material information along with the location of any fog, rain and smoke particles, i.e. small particulates which are determined not to be target objects) to produce segmented point cloud data. Labels 412 and spectral shape recognition techniques 414 may also be used in the determination of segmented point cloud data 418, as may techniques 416 for approximating and discriminating object (generally based on machine learning).

As previously described, the AI module 40 and the LCM 20 may control the LTM 10 based on environmental information and information from other sensors. Such control may be based on correlations between multiple sensors which are inferred in real-time by the AI module 40, rather than (or in addition to) explicit classifications for particular conditions.

FIG. 5 shows a schematic diagram showing the control mechanism for the transmitting parts of the system 100 (i.e. the LTM 10). Transmitters 10 transmit into the environment 110, and backscattered radiation is received by the system's receivers (i.e. the LRM 30). The receivers 30 communicate information to the AI module 40, which communicates with a transmission control module (i.e. the light controller 20). Other sensors (e.g. the vehicle radar/ultrasound 50, the internal sensors 60, and/or the external camera 70) also communicate with either or both of the AI module 40 and the transmission control module 20. The AI module 40 and the transmission control module 20 communicate with each other continuously, such that control parameters are fed into the AI module for comparison with the actual detected results. Different transmitters (optionally from different types of sensors) may be controlled using the control parameters—when fed back to the AI module and compared with detected results, this may allow correlations between different sensors to be learnt and control to be adapted accordingly. This may allow sensor parameters to be (at least semi-automatically) adapted in real time in accordance with changes detected by other sensors—for example, where one sensor detects that visibility is getting worse (e.g. due to increased fog or rain), the power of a transmitter of another sensor may be increased accordingly.

FIGS. 6a and 6b show examples of different sensor data received by the system 100. Correlations between sensors may be cross-learned for use in control, as described. FIG. 6a shows static data, while FIG. 6b shows live data. The AI module learns cross-learnt dictionaries, and inferences made based on the cross-learnt dictionaries enables the system to control sensor parameters automatically depending on the environment in which the system (or the vehicle including the system) is located.

FIG. 7 shows a computer device 1000 suitable for implementing the described methods and/or forming part of the described system 100. The computer device 1000 may implement some or all of the described software modules.

The computer device 1000 comprises a processor in the form of a CPU 1002, a communication interface 1004, a memory 1006, storage 1008, removable storage 1010 and a user interface 1012 coupled to one another by a bus 1014. The user interface 1012 comprises a display 1016 and an input/output device, which in this embodiment is a keyboard 1018 and a mouse 1020. In other embodiments, the input/output device comprises a touchscreen (such as one that might be suitably included in that dashboard of a vehicle). It will be appreciated that a GPU or FPGA may be used in place of or in combination with the CPU 1002. Alternative input/output device (or human-machine interfaces) may be used—for example, data may be projected via a VR/AR device and the user interaction may take place via gesture recognition.

The computer device is provided in communication with one or more sensors 1003, as previously described herein.

The CPU 1002 executes instructions, including instructions stored in the memory 1006, the storage 1008 and/or removable storage 1010. The memory 1006 stores instructions and other information for use by the CPU 1002. The memory 1006 is the main memory of the computer device 1000. It usually comprises both Random Access Memory (RAM) and Read Only Memory (ROM).

The storage 1008 provides mass storage for the computer device 1000. In different implementations, the storage 1008 is an integral storage device in the form of a hard disk device, a flash memory or some other similar solid state memory device, or an array of such devices.

The removable storage 1010 provides auxiliary storage for the computer device 1000. In different implementations, the removable storage 1010 is a storage medium for a removable storage device, such as an optical disk, for example a Digital Versatile Disk (DVD), a portable flash drive or some other similar portable solid state memory device, or an array of such devices. In other embodiments, the removable storage 1010 is remote from the computer device 1000, and comprises a network storage device or a cloud-based storage device.

A computer program product is provided that includes instructions for carrying out aspects of the method(s) described below. The computer program product is stored, at different stages, in any one of the memory 1006, storage device 1008 and removable storage 1010. The storage of the computer program product is non-transitory, except when instructions included in the computer program product are being executed by the CPU 1002, in which case the instructions are sometimes stored temporarily in the CPU 1002 or memory 1006. It should also be noted that the removable storage 1008 is removable from the computer device 1000, such that the computer program product is held separately from the computer device 1000 from time to time.

The communication interface 1004 is typically an Ethernet network adaptor coupling the bus 1014 to an Ethernet socket. The Ethernet socket is coupled to a network.

It will be appreciated that any of the described components of the computer device 1000 may be located away from the computer, for example via one or more external servers (i.e. where processing takes place in “the cloud”). The computer device 1000 may be included on-board a vehicle.

### Alternatives and Extensions

It will be appreciated that the system 100 described with reference to FIG. 1 is only an exemplary embodiment of the system, and that various other configurations could instead be used to implement the invention. In particular, the AI module 40 may in an alternative directly receive input from the processors 52 and so may perform some or all of the described functions of the processor 52 of the LRM 30, including building and gating histograms.

The various modules may alternatively be combined or split up into further discrete components, and may be implemented in hardware, software, or a combination of hardware and software. In particular, the LCM 20 may be an embedded (software-on-chip) piece of software in the LTM 10 or another module.

Although the system has generally been described with reference to processing taking place in the system/on a vehicle, it will be appreciated that any described processing may alternatively take place at an external remote server (which may be a ‘cloud server’), wherein the system comprises a suitable transceiver for transmitting an input to the remote server and for receiving an output from the remote server. Accordingly, any of the described modules or components (apart from at least the laser of the LTM 10 and the detectors 32 of the LRM 30, i.e. the minimum components of the LIDAR device of the system) may be provided remotely from the system/vehicle at a server.

Where any operations or processing has been described with reference to histograms formed based on the received signal, it will be appreciated that such operations/processing may (in suitably adapted form) be applied to the raw received signal itself, and vice versa.

Optionally, the AI module is configured to produce a profile of the detected object, including several parameters, such as type, speed, size, shape, etc.

Optionally, the object(s) detected using the system comprise one or more airborne particles and/or objects associated with precipitation, rather than (or in addition to) an object that is not either of the above. Optionally, the system may be used to determine a measure of the visibility of the conditions by detecting airborne particles and/or objects associated with precipitation, which may be used as an input for the AI module 40 and/or in gating the histograms.

Optionally, gating the histograms comprises defining the properties (e.g. width) of the categories/bins of the histograms and/or the start and stop locations of the gate.

Optionally, the processor 52 is configured to generate further histograms related to a plurality of parameters of the signal and/or different category sizes related to a single parameter—for example, such further histograms may relate to a plurality of different wavelength ranges (where each wavelength range is normally used as a category size by the previously described histograms, such that the further histograms have relatively large category sizes). Such further histograms may be used as an input into the AI module 40 and/or may be transmitted away from the system 100 for further analysis.

Although the system 100 has generally been described with reference to the use of other ranging systems for providing a further input for gating a light-based (LIDAR) system, it will be appreciated that the invention may extend to using any ranging system to gate any other ranging system, in particular in any circumstance in which the other ranging system operates more reliably but lacks resolution or accuracy of results.

Although the system 100 has principally been described with reference to an implementation as part of a navigation system of a vehicle (for example, a UAV (or ‘drone)’ or a small service robot, or a passenger vehicle), it will be appreciated that the invention could also be used as part of any machine, in particular an autonomous machine. Such machines may be static or dynamic. In particular, the system could be implemented as part of a structure, or a tethered device such as a drone or a balloon. The system could also be implemented as part of an infrastructure monitoring system, such as a static camera system, for example for the purpose of security monitoring.

The invention may in particular be applied for underwater applications. In this case, all references to “aerosols” or “airborne particles” can be understood to refer to “waterborne particles” (e.g. in murky water).

The invention may alternatively be implemented in a variety of other fields and/or applications—for example, in devices for measurement or sensing, infrastructure inspection, industrial processing, or mapping (for example, in agriculture, geomatics, archaeology, geography, geology, geomorphology, seismology, forestry, atmospheric physics, laser guidance, airborne laser swath mapping (ALSM), and laser altimetry). The system may find particular use in applications where GNSS/GPS systems are not suitable (due to poor signal availability) and/or where camera-based systems are not suitable (due to low light, for example), such as sewer navigation, inspection, and mapping, underground mining (in particular for surveying), nuclear decommissioning, petrochemical plant inspections, security, agriculture, and ship hull inspections.

It will be understood that the invention has been described above purely by way of example, and modifications of detail can be made within the scope of the invention.

Each feature disclosed in the description, and (where appropriate) the claims and drawings may be provided independently or in any appropriate combination.

Reference numerals appearing in the claims are by way of illustration only and shall have no limiting effect on the scope of the claims.

1. A system for detecting at least one object in environmental conditions of poor visibility, comprising:
a ranging device configured to receive a set of signals;
at least one further ranging device configured to receive at least one further set of signals; and
a processor configured to gate the set of signals based on the at least one further set of signals thereby to identify at least one subset of the set of signals, the at least one subset of signals relating to at least one object.

2. A system according to claim 1, wherein the ranging device comprises an emitter of electromagnetic radiation.

3. A system according to claim 2, wherein the emitter of electromagnetic radiation comprises a laser.

4. A system according to any preceding claim , wherein the at least one object is not any of: an aerosol; one or more airborne particles; and precipitation.

5. A system according to any preceding claim, wherein the ranging device is light-based and the at least one further ranging device is not light-based.

6. A system according to claim 5, wherein the at least one further ranging device provides greater penetration of airborne particles and precipitation than the ranging device.

7. A system according to claim 5 or 6, wherein the at least one further ranging device comprises a radar device.

8. A system according to any of claims 5 to 7, wherein the at least one further ranging device comprises a sound-based ranging device, such as an ultrasound-based ranging device.

9. A system according to any preceding claim, wherein the ranging device is arranged to operate continuously.

10. A system according to claim 9, wherein the processor is configured to record the receipt of signals in the set of signals over a time period.

11. A system according to claim 10, wherein the processor is configured to generate at least one histogram relating to the set of signals.

12. A system according to any preceding claim, wherein the processor is configured to control the properties of the gating.

13. A system according to any preceding claim, wherein the processor is configured to gate the set of signals in real time.

14. A system according to any preceding claim, further comprising a classification module configured to identify the at least one object related to the at least one subset of signals by reference to a plurality of predetermined classes.

15. A system according to claim 14, wherein the classification module is configured to identify the at least one object by identifying features of the subset of signals; and comparing the identified features against the plurality of predetermined classes.

16. A system according to claim 15, wherein said identifying and comparing are performed simultaneously.

17. A system according to any of claims 14 to 16, wherein the classification module comprises a trained classifier.

18. A system according to any of claims 14 to 17, wherein the classification module is configured to receive feedback and update the plurality of predetermined classes in response to said feedback.

19. A system according to any of claims 14 to 18, wherein the classification module is further configured to classify the at least one object by one or more of: type; shape; material; and movement.

20. A system according to any of claims 14 to 19, wherein the classification module is configured to operate in real time.

21. A system according to any of claims 14 to 20, wherein the classification module is configured to identify the at least one object based on input from the at least one further ranging device.

22. A system according to any of claims 14 to 21, further comprising at least one further sensor, wherein the classification module is configured to identify the at least one object based on input from the at least one further sensor.

23. A system according to claim 22, wherein the at least one further sensor comprises one or more of: an inertial measurement unit, an accelerometer, a camera, and a Global Navigation Satellite System (GNSS) or Global Positioning System (GPS) receiver.

24. A system according to any of claims 14 to 23, wherein the classification module is configured to identify the at least one object based on weather data.

25. A system according to any preceding claim, wherein the processor is configured to provide a dictionary of elementary shape functions for a waveform; determine a vector relating to the contribution of each elementary function in the dictionary to the waveform of at least one signal in the set of signals; and classify the waveform of the at least one signal based on the vector thereby to detect at least one object.

26. A system according to any preceding claim, wherein the ranging device comprises a light detection and ranging (LI DAR) device and the set of signals comprises reflected photons originating from a transmitted pulse of the ranging device.

27. A system according to claim 26, wherein the LIDAR device comprises a plurality of single photon detectors for receiving reflected photons, preferably wherein the plurality of single photon detectors comprises single-photon avalanche diodes (SPADs).

28. A system according to claim 27, wherein the plurality of single photon detectors are tuned to receive a plurality of different wavelengths of reflected photons.

29. A system according to any of claims 26 to 28, wherein the LIDAR device has a 360 degree field of view.

30. A system according to any of preceding claim, wherein the processor is further configured to control the operation of the ranging device based on data relating to environmental conditions received from at least one sensor.

31. A system according to claim 30, wherein the at least one sensor is part of one or more of: the ranging device; and the at least one further ranging device.

32. A system for detecting at least one object in environmental conditions of poor visibility, comprising:
a ranging device configured to receive a set of signals;
at least one sensor for receiving data relating to environmental conditions; and
a processor configured to control the operation of the ranging device in dependence on the received data.

33. A system according to claim 32, wherein the ranging device comprises an emitter of electromagnetic radiation.

34. A system according to claim 33, wherein the emitter of electromagnetic radiation comprises a laser.

35. A system according to any of claims 32 to 34, wherein the at least one sensor is part of a further ranging device.

36. A system according to claim 35, wherein the further ranging device comprises a radar device.

37. A system according to claim 35 or 36, wherein the further ranging device comprises a sound-based ranging device, such as an ultrasound-based ranging device.

38. A system according to any of claims 30 to 37, wherein the processor is configured to control the operation of the ranging device based on determined correlations between the ranging device and the at least one sensor.

39. A system according to any of claims 30 to 38, wherein the at least one sensor comprises one or more of: an inertial measurement unit, an accelerometer, a camera, and a Global Navigation Satellite System (GNSS) or Global Positioning System (GPS) receiver.

40. A system according to any of claims 30 to 39, wherein the at least one sensor comprises a receiver for receiving data via a data network.

41. A system according to any of claims 30 to 40, comprising a plurality of different sensors external to the ranging device for receiving data relating to environmental conditions.

42. A system according to any of claims 30 to 41, wherein the processor is configured to control the operation of the ranging device by controlling one or more of: frequency; frequency modulation; pulse width; pulse repetition rate; field of view; resolution; beam width; wavelength; and power.

43. A system according to any of claims 30 to 42, wherein the processor is configured to control the operation of the ranging device in real time.

44. A system according to any of claims 30 to 43, wherein the ranging device is configured to receive further data relating to environmental conditions; wherein the processor is configured to control the operation of the ranging device in dependence on the received further data.

45. A system for navigation comprising the system of any of claims 1 to 44, wherein the at least one object is relevant for navigation.

46. A method of detecting at least one object, comprising the steps of:
receiving a set of signals via a ranging device;
providing a dictionary of elementary shape functions of a waveform;
determining a vector relating to the contribution of each elementary shape function in the dictionary to the shape of the waveform of at least one signal in the set of signals; and
classifying the at least one signal based on the vector thereby to detect at least one object.

47. A method according to claim 46, wherein the determining and classifying are performed simultaneously.

48. A method according to claim 46 or 47, further comprising identifying peaks in the at least one set of signals, wherein the vector is determined based on at least one peak.

49. A method according to claim 48, further comprising ranking the peaks; and
repeatedly determining a vector in respect of a plurality of peaks, wherein the peaks are processed in ranked order.

50. A method according to claim 49, further comprising repeatedly determining a vector in respect of a plurality of peaks until a stop criterion, optionally a pre-determined threshold is met.

51. A method according to any of claims 48 to 50, further comprising determining sparse parameters of the waveform from the identified peaks, preferably wherein said sparse parameters are used in the determination of the vector.

52. A method according to claim 51, further comprising generating the dictionary based on the sparse parameters of the waveform.

53. A method according to any of claims 49 to 52, further comprising detecting at least one object, preferably wherein said detecting comprises detecting at least one of: the class of the object; the type of the object; the distance of the object from the ranging device; and the material of the object.

54. A system comprising:
a non-transitory memory storing instructions or local data; and
one or more hardware processors coupled to the non-transitory memory and configured to execute the instructions from the non-transitory memory to cause the system to perform operations comprising the steps of any of claims 46 to 53.

55. A sensing device comprising the system of any of claim 1 to 45 or 54.

56. A vehicle comprising the system of any of claim 1 to 45 or 54.

57. A vehicle according to claim 56, wherein the vehicle is configured for use in one or more of the following environments: underground; underwater; on a road; on a railway; on the surface of water; in high altitude; and in low altitude.

58. A vehicle according to claim 56 or 57, wherein the vehicle is one of: a mobile robot; an unmanned underwater vehicle (UUV); a submarine; a ship; a boat; a train; a tram; an aeroplane; an unmanned aerial vehicle (UAV); and a passenger vehicle such as a car.

59. A method of detecting at least one object in environmental conditions of poor visibility, comprising:
receiving a set of signals via a ranging device;
receiving at least one further set of signals using at least one further ranging device; and
gating the first set of signals based on the at least one further set of signals thereby to identify at least one subset of the set of signals, the at least one subset of signals relating to at least one object.

60. A method of controlling an object detection system, comprising the steps of:
providing an object detection system comprising a ranging device;
receiving data relating to environmental conditions from the at least one sensor; and
controlling the operation of the laser in dependence on the received data.

61. A computer program product comprising software code adapted to carry out the method of any of claim 46 to 53; 59; or 60.
